(19) United States
(12) Patent Application Publication
(10) Pub. No.: US 2026/0203209 A1
(43) Pub. Date: Jul. 16, 2026

(54) MEMORY SYSTEMS AND OPERATION METHODS, CONTROLLERS, MEMORY DEVICES AND SYSTEMS THEREOF

(71) Applicant: Yangtze Memory Technologies Co., Ltd., Wuhan (CN)

(72) Inventors: Biao Yang, Wuhan (CN); Xingwei Tang, Wuhan (CN)

(21) Appl. No.: 19/182,344

(22) Filed: Apr. 17, 2025

(30) Foreign Application Priority Data
Jan. 13, 2025 (CN) 202510052239.1

(51) Int. Cl. G06F 12/02; G11C 16/04; G11C 16/28

(52) U.S. Cl. CPC G06F 12/0246; G11C 16/28; G11C 16/0483

(57) ABSTRACT

Disclosed example methods of memory systems include: performing first read operations on multiple target memory cells based on a first set of read voltages to obtain a first set of read results; obtaining a first set of read reference voltages based on the first set of read results and level indicators of the multiple target memory cells; performing a plurality of second read operations on the multiple target memory cells based on a second set of read voltages to obtain a second set of read results; obtaining a second set of read reference voltages based on the second set of read results and level indicators of the multiple target memory cells; performing a plurality of third read operations on the multiple target memory cells based on the first set of read reference voltages and the second set of read reference voltages to obtain a third set of read results.

### CROSS-REFERENCE TO RELATED APPLICATION

This application claims priority to and the benefit of Chinese Patent Application 202510052239.1, filed on Jan. 13, 2025, which is hereby incorporated by reference in its entirety.

### TECHNICAL FIELD

The present disclosure relates to the field of semiconductor technology, and involves memory systems and operation methods, controllers, memory devices, systems, and non-transitory computer-readable storage media thereof.

### BACKGROUND

With the rapid development of data storage technology, more and more data memory systems are appearing in electronic devices used by people, such as Secure Digital Memory Card (SD card), Universal Flash Storage (UFS), Solid State Drive (SSD), etc.

### BRIEF DESCRIPTION OF THE DRAWINGS

FIG. 1 is a schematic diagram of an example system having a memory system according to an implementation of the present disclosure.

FIG. 2 is a schematic diagram of a memory card according to an implementation of the present disclosure.

FIG. 3 is a schematic diagram of a solid-state drive according to an implementation of the present disclosure.

FIG. 4 is a circuit schematic diagram of an example memory device including a peripheral circuit according to an implementation of the present disclosure.

FIG. 5 is a schematic diagram of a memory device according to an implementation of the present disclosure.

FIG. 6 is a flowchart of an operation method of a memory system according to an implementation of the present disclosure.

FIG. 7 is a first schematic diagram of threshold voltage distributions of multiple target memory cells according to an implementation of the present disclosure.

FIG. 8 illustrates data stored in multiple target memory cells and corresponding level indicators according to an implementation of the present disclosure.

FIG. 9 is a schematic diagram of threshold voltage distributions of a first set of memory cells and a second set of memory cells according to an implementation of the present disclosure.

FIG. 10 is a schematic diagram of selection of read voltages of a set of first read operations according to an example of the present disclosure.

FIG. 11 is a schematic diagram of selection of read voltages of a set of second read operations according to an example of the present disclosure.

FIG. 12 is a second schematic diagram of threshold voltage distributions of multiple target memory cells according to an implementation of the present disclosure.

FIG. 13 is a schematic diagram of a controller according to an implementation of the present disclosure.

FIG. 14 is a schematic diagram of a memory system according to an implementation of the present disclosure.

FIG. 15 is a first schematic diagram of a system including a memory array and a control circuit according to an implementation of the present disclosure.

FIG. 16 is a second schematic diagram of a system including a memory array and a control circuit according to an implementation of the present disclosure.

FIG. 17 is a third schematic diagram of a system including a memory array and a control circuit according to an implementation of the present disclosure.

### DETAILED DESCRIPTION

Example implementations disclosed in the present disclosure will be described in more detail below with reference to the drawings. Although example implementations of the present disclosure are illustrated in the drawings, it should be understood that the present disclosure may be implemented in various manners and should not be limited to the implementations set forth herein. Rather, these implementations are provided so that the present disclosure may be understood more thoroughly and the scope of the present disclosure may be fully presented to those skilled in the art.

Numerous details are introduced hereinafter in order to provide a more thorough understanding of the present disclosure. However, it would be obvious to one skilled in the art that, the present disclosure may be practiced without one or more of these details. In other examples, in order to avoid a confusion with the present disclosure, some technical features known in the art are not described; that is, not all the features of the actual implementations are described herein, and well-known functions and structures are not described in detail.

In the drawings, the same references refer to the same elements throughout.

It should be appreciated that terms of spatial relationship such as “beneath,” “below,” “lower,” “under”, “above”, “upper,” etc., may be used herein for ease of description, so as to describe the relationships between one element or feature and other elements or features shown in the drawings. It should be appreciated that, in addition to the orientations shown in the drawings, the terms of spatial relationship are intended to further include different orientations of a device in use and operation. For example, if the devices in the drawings are inverted, then elements or features described as “below” or “under” or “beneath” other elements or features would be oriented “on” the other elements or features. Thus, the example terms “below” and “under” may comprise both upper and lower orientations. The devices may be additionally oriented (rotated 90 degrees or other orientations) and the spatial description terms used herein may be interpreted accordingly.

A term used herein is merely for the purpose of describing an implementation and is not limiting the present disclosure. As used herein, unless the context indicates otherwise clearly, the singular form of “a”, “an” and “said/the” are intended to comprise the plural form as well. It should also be understood that the terms of “composed of” and/or “comprising”, when used in the description, indicates a presence of the stated features, integers, steps, operations, elements and/or components, rather than exclude a presence and addition of one or more other features, integers, steps, operations, elements, components and/or groups. As used herein, term “and/or” comprises any and all combinations of the related listed items.

A memory system in an example of the present disclosure includes but is not limited to a memory system including a three-dimensional NAND type memory. For ease of understanding, a memory system including a three-dimensional NAND type memory may be taken as an example for illustration of the memory system provided in the present disclosure.

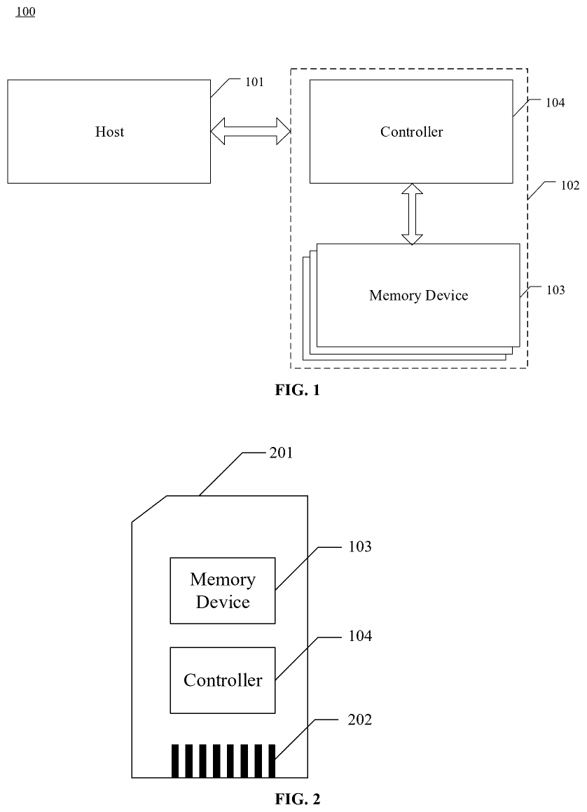

FIG. 1 is a schematic diagram of an example system having a memory system according to an implementation of the present disclosure. In an example of the present disclosure, the system 100 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory therein. As shown in FIG. 1, the system 100 may comprise a host 101 and a memory system 102, the memory system 102 may comprise one or more memory devices 103 and a controller 104. The host 101 may comprise a processor of an electronic device, for example, a Central Processing Unit (CPU), or a System on a Chip (SoC), such as an application processor (AP). The host 101 may be configured to transmit data to or receive data from the memory system 102.

In some examples, the controller 104 is coupled to the memory device 103 and the host 101, and is configured to control the memory device 103. The controller 104 may manage data stored in the memory device 103 and communicate with the host 101. In some examples, the controller 104 is designed to operate in a low duty cycle environment, such as in a secure digital card, Compact Flash Card (CFC), Universal Serial Bus (USB) flash driver, or to operate in other medium for use in electronic device such as personal computer, digital camera, mobile phone, and the like. In further examples, the controller 104 is designed to operate in a high duty cycle environment, such as in a solid state disk or embedded Multi-Media Card (eMMC).

In some examples, the controller 104 and the one or more memory devices 103 may be integrated into various types of storage devices, that is, the memory system 102 may be implemented and packaged into different types of terminal electronic products.

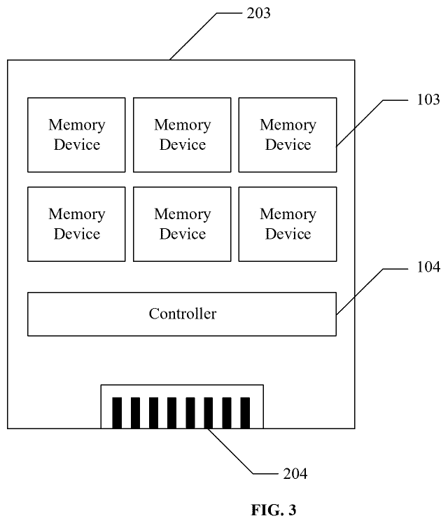

In one example as shown in FIG. 2, the controller 104 and a single memory device 103 may be integrated into a memory card 201. The memory card 201 may be one of a compact flash memory card, a Smart Media Card (SMC), a Memory Stick (MS), a Multi-Media Card (MMC), such as Reduced-Size MMC (RS-MMC), MMCmicro, eMMC or the like, a secure digital (SD) card, such as Mini SD card, Micro SD card, Secure Digital High Capacity (SDHC) card or the like, and a universal flash memory card. The memory card 201 may also comprise a memory card connector 202 that couples the memory card 201 with a host (e.g., host 101 in FIG. 1). In another example as shown in FIG. 3, the controller 104 and a plurality of memory devices 103 may be integrated into SSD 203. The SSD 203 may also comprise an SSD connector 204 that couples SSD 203 with a host (e.g., host 101 in FIG. 1). In some examples, the storage capacity and/or operating speed of SSD 203 is greater than the storage capacity and/or operating speed of the memory card 201.

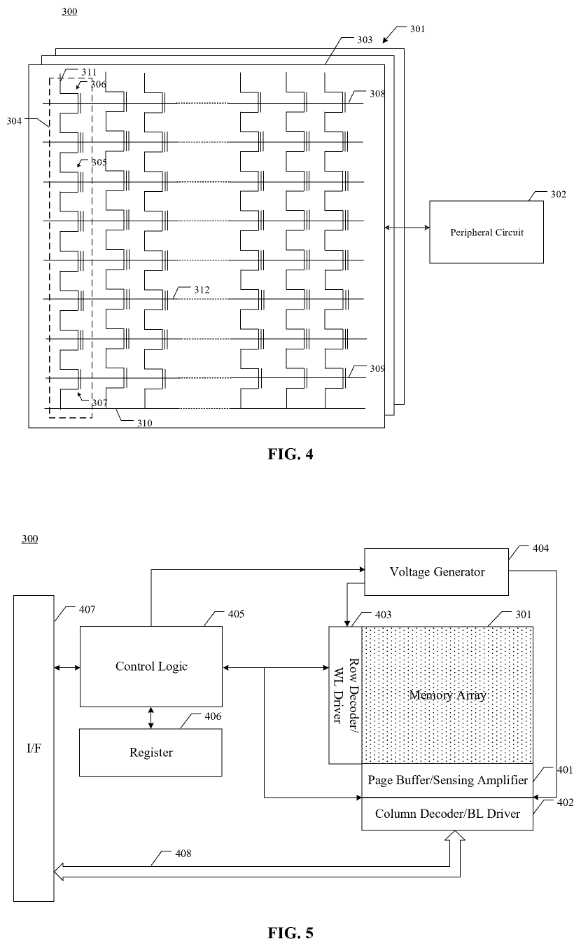

FIG. 4 is a schematic circuit diagram of an example memory device 300 comprising a peripheral circuit according to an implementation of the present disclosure. The memory device 300 may be an example of the memory device 103 in FIG. 1. The memory device 300 may comprise a memory array 301 and a peripheral circuit 302 coupled to the memory array 301. Taking the memory array 301 of a 3D NAND memory array as an example for description, wherein a memory cell 305 is a NAND memory cell, the memory cell 305 is provided in the form of memory strings 304, each memory string 304 extends vertically above a substrate (not shown). In some examples, each memory string 304 comprises a plurality of memory cells 305 coupled in series and stacked vertically. Each memory cell 305 may maintain a continuous analog value, e.g., voltage or charge, which depends on the number of electrons trapped within the region of the memory cell 305. Each memory cell 305 may be a memory cell of floating gate type which comprises a floating gate transistor or a memory cell of charge trap type which comprises a charge trap transistor.

In some examples, each memory cell 305 is a Single Level Cell (SLC), having two possible memory states and thus may store one bit of data. For example, a first memory state “0” may correspond to a first threshold voltage distribution and a second memory state “1” may correspond to a second threshold voltage distribution. In some examples, each memory cell 305 is a multi-level cell, which is capable of storing more than a single bit of data in four or more memory states, e.g., a Multi-Level Cell (MLC) storing two bits per cell, a Triple Level Cell (TLC) storing three bits per cell, or a Quad-Level Cell (QLC) storing four bits per cell.

As shown in FIG. 4, each memory string 304 may comprise a Bottom Select Transistor (BST) 307 at its source end and a Top Select Transistor (TST) 306 at its drain end. The bottom select transistor 307 and the top select transistor 306 may be configured to activate a selected memory string 304 during read and program operations.

In some implementations, the memory array 301 includes multiple memory blocks 303, and sources of the memory strings 304 in a same memory block 303 may be coupled through a Common Source Line (CSL) 310. In other words, all the memory strings 304 in the same memory block 303 have a common source (ACS). According to some implementations, a top select transistor 306 of each memory string 304 is coupled to a respective Bit Line (BL) 311, data may be read or written via an output bus (not shown) from the bit line 311. In some implementations, each memory string 304 is configured to be selected or deselected by applying a select voltage (e.g., a voltage higher than a threshold voltage of the top select transistor 306) or a deselect voltage (e.g., 0V) to a Top Select Gate (TSG) of a respective top select transistor 306 through one or more Top Select Lines (TSL) 308 and/or by applying a select voltage (e.g., a voltage higher than a threshold voltage of the bottom select transistor 307) or a deselect voltage (e.g., 0V) to a Bottom Select Gate (BSG) of a respective bottom select transistor 307 through one or more Bottom Select Lines (BSL) 309.

In some implementations, each memory block 303 is a basic data unit for an erase operation, e.g., all the memory cells 305 on a same memory block 303 may be erased simultaneously. To erase the memory cells 305 in a selected memory block, a common source line 310 coupled to the selected memory block and an unselected memory block(s) in the same plane as the selected memory block may be biased with an erase voltage. It should be understood that, in some examples, an erase operation may be performed at a half-memory block level, at a quarter-memory block level, or at a level with any suitable number of memory blocks or any suitable fraction of a memory block. Memory cells 305 of adjacent memory strings 304 may be coupled by a word line 312, the word line 312 selects which row of memory cells 305 are affected by read or program operations.

In some examples, the peripheral circuit 302 may comprise any suitable analog, digital, and mixed-signal circuit, in order to enable an operation on the memory array 301 by applying at least one of a voltage signal or a current signal to each target memory cell 305 and sensing at least one of a voltage signal or a current signal from each target memory cell 305 through the bit line 311, the word line 312, the common source line 310, the bottom select line 309, and the top select line 308. The peripheral circuit 302 may comprise various types of peripheral circuits formed with metal-oxide-semiconductor technology.

FIG. 5 is a schematic diagram of a memory device according to an example of the present disclosure. Referring to FIGS. 4 and 5, the peripheral circuit 302 may include a page buffer/sensing amplifier 401, a column decoder/bit line driver 402, a row decoder/word line driver 403, a voltage generator 404, a control logic 405, a register 406, a flash memory interface 407, and a data bus 408. It should be understood that, in some examples, the peripheral circuit may also include an additional circuit not shown in FIG. 5.

The page buffer/sensing amplifier 401 may be configured to read data from the memory array 301 and program (write) data to the memory array 301 according to a control signal from the control logic 405. In one example, the page buffer/sensing amplifier 401 may store a page of programming data (write data) to be programmed to the memory array 301. In another example, the page buffer/sensing amplifier 401 may perform a programming verification operation to ensure that the data has been properly programmed into memory cells coupled to the selected word line. In yet another example, the page buffer/sensing amplifier 401 may also sense a low power signal from the bit line, representing a data bit stored in the memory cell, and may amplify a small voltage swing to an identifiable logic level in a read operation. The column decoder/bit line driver 402 may be configured to be controlled by the control logic 405 and select one or more memory strings by applying a bit line voltage generated from the voltage generator 404.

The row decoder/word line driver 403 may be configured to be controlled by the control logic 405 and select/deselect a memory block of the memory array 301 and select/deselect a word line of the memory block. The row decoder/word line driver 403 may also be configured to drive a word line using a word line voltage generated from the voltage generator 404. In some examples, the row decoder/word line driver 403 may also select/deselect and drive a bottom select line and a top select line. As described in detail hereinafter, the row decoder/word line driver 403 is configured to perform a programming operation on memory cells coupled to the selected word line(s). The voltage generator 404 may be configured to be controlled by the control logic 405 and generate a word line voltage (e.g., a reading voltage, a programming voltage, a passing voltage, a local voltage, a verifying voltage, etc.), a bit line voltage, and a source line voltage to be supplied to the memory array 301.

The control logic 405 may be coupled to each peripheral circuit described above, and configured to control operation of each peripheral circuit. The register 406 may be coupled to the control logic 405, and comprises a status register, a command register, and an address register for storing status information, command operation code (OP code), and command address for controlling the operation of each peripheral circuit. The flash memory interface 407 may be coupled to the control logic 405 and act as a control buffer to buffer a control command received from a host (not shown) and relay it to the control logic 405, and buffer status information received from the control logic 405 and relay it to a controller. The flash memory interface 407 may also be coupled to the column decoder/bit line driver 402 via the data bus 408, and act as a data input/output (I/O) interface and a data buffer to buffer data and relay it to the memory array 301 or buffer and relay data from the memory array 301.

For a three-dimensional NAND memory, with an increase of the storage density of memory, the number of stacked layers is growing, as well as the coded number, the efficiency and reliability of programming operations would decrease accordingly. In order to improve the efficiency and reliability of programming operations at the same time, Multi-Pass Programming has been proposed to perform programming operations on multi-level cells. For example, a threshold voltage of a memory cell may be adjusted to be close to a threshold voltage distribution corresponding to a target programming state by Coarse Programming with a faster programming speed, then the threshold voltage of the memory cell is adjusted to be within the range of the threshold voltage distribution corresponding to the target program state by Fine Programming with a relatively slow programming speed, thereby a balance between the programming efficiency and the reliability may be achieved.

However, in order to make a coarse programming operation faster, a higher programming voltage may be used to inject charges into a memory cell quickly, but it would lead to a shorter readable life of coarse programming data. If the memory is abnormally powered down at this time, the coarse programmed data needs to be flushed from a multi-level cell to a single-level cell (SLC) to ensure the data integrity and reliability, it may bring a large gap of electrical demand of capacitor being abnormally powered down, which becomes an important problem limiting the development of enterprise level solid-state drive.

In some examples, performing a read operation on the coarse programmed data using a level indicator may extend the readable life of the coarse programmed data. In order to fully utilize the functionality of the level indicator, a valley search method adapted to the level indicator may be needed to determine an optimal read voltage, in order to further improve the data reliability.

In this regard, the following implementations are proposed in the present disclosure.

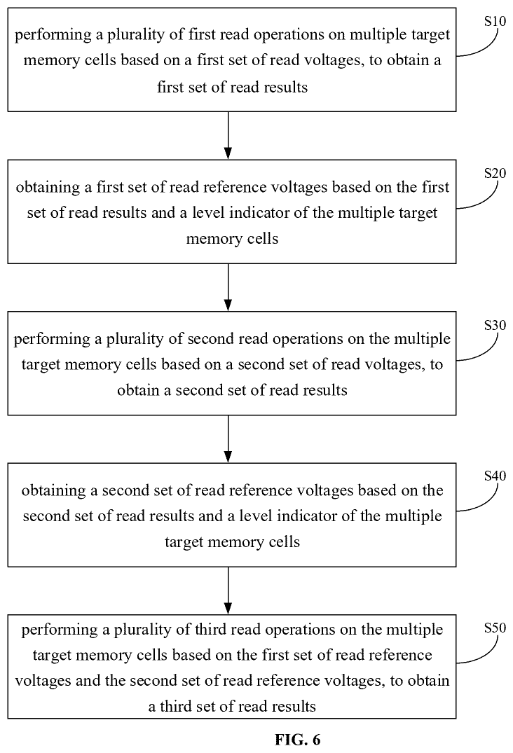

The present disclosure provides an operation method of a memory system. FIG. 6 is a flowchart of an operation method of a memory system. As shown in FIG. 6, the operation method of the memory system includes the following operations:
Operation S10: performing a plurality of first read operations on multiple target memory cells based on a first set of read voltages, to obtain a first set of read results;
Operation S20: obtaining a first set of read reference voltages based on the first set of read results and level indicators of the multiple target memory cells;
Operation S30: performing a plurality of second read operations on the multiple target memory cells based on a second set of read voltages, to obtain a second set of read results;
Operation S40: obtaining a second set of read reference voltages based on the second set of read results and level indicators of the multiple target memory cells; and
Operation S50: performing a plurality of third read operations on the multiple target memory cells based on the first set of read reference voltages and the second set of read reference voltages, to obtain a third set of read results.

In the examples, any one of the multiple target memory cells stores N bits of data, wherein N is an integer greater than 1; and the operation method of the memory system further comprises: obtaining a level indicator of each target memory cell based on the N bits of data stored in each target memory cell, wherein the multiple target memory cells include a first set of memory cells that store 2^{N-1} different types of data and a second set of memory cells that store 2^{N-1} different types of data, and wherein the level indicator of the first set of memory cells is different than the level indicator of the second set of memory cells.

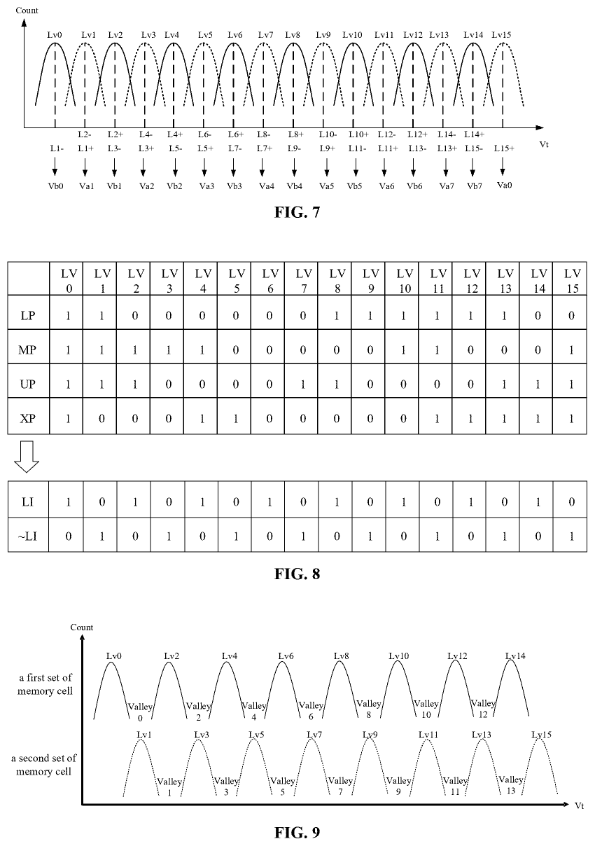

In some examples, taking N being 4 as an example, FIG. 7 shows threshold voltage distributions of multiple target memory cells, and FIG. 8 shows data stored in multiple target memory cells and the corresponding level indicators. Referring to FIGS. 7 and 8, when any one of the multiple target memory cells stores four bits of data, the multiple target memory cells may have sixteen memory states (Lv0 to Lv15), and each memory state may correspond to one four-bit data. By performing an XOR operation on the four-bit data stored in each target memory cell, the level indicator LI of the target memory cell may be obtained. For example, if the four-bit data stored in the target memory cell is 1111, its level indicator LI is 0; and if the four-bit data stored in the target memory cell is 1110, its level indicator LI is 1.

Furthermore, the multiple target memory cells may be divided into a first set of memory cells and a second set of memory cells by the level indicators LI. FIG. 9 is a schematic diagram of threshold voltage distributions of the first set of memory cells and the second set of memory cells according to an example of the present disclosure. Referring to FIGS. 8 and 9, the multiple target memory cells include a first set of memory cells that store eight different types of data and a second set of memory cells that store eight different types of data, and the level indicator LI of the first set of memory cells is different from the level indicator LI of the second set of memory cells. Here, the level indicator LI of the first set of memory cells may be 0, and the level indicator LI of the second set of memory cells may be 1.

In some examples, 2^{N} default read voltages may be used to perform read operations on multiple target memory cells, and data stored in the target memory cells may be obtained using a logical operation on the level indicator LI and the read results. For example, referring to FIGS. 7 and 8, a four-bit data stored in the target memory cell may belong to four class pages: Lower Page (LP), Middle Page (MP), Upper Page (UP), and Extra Page (XP). When reading data stored in multiple target memory cells, read operations may be performed on a per class page basis. The default read voltage may be a voltage corresponding to a peak value of a cell count of each threshold voltage distribution. Taking reading of the data of LP as an example, read operations may be performed on multiple target memory cells by a set of read voltages (read voltages corresponding to L4+, L6+, and L10+), to obtain a set of read data (D1). Then, read operations may be performed on the multiple target memory cells by another set of read voltages (read voltages corresponding to L4−, L6−, and L10−), to obtain another set of read data (D2). Subsequently, AND operations may be performed on D1 and the level indicators LI of each target memory cell, and AND operations may be performed on D2 and the inverted level indicator ~LI of each target memory cell, and then the results of the two AND operations may be added to obtain the data of LP.

Here, for the first set of memory cells, if its level indicator LI is 0, its inverted level indicator ~LI is 1; and for the second set of memory cells, if its level indicator LI is 1, its inverted level indicator ~LI is 0.

However, the threshold voltages of multiple target memory cells may drift, resulting in reduced reliability of read operation using the default read voltage. Therefore, a valley search operation may be needed to optimize the read voltage.

In some examples, the operation method of the memory system further comprises: acquiring 2^{N-1}−1 default read voltages of the second set of memory cells as 2^{N-1}−1 first initial read voltages in the first set of read voltages; and acquiring 2^{N-1}−1 default read voltages of the first set of memory cells as 2^{N-1}−1 second initial read voltages in the second set of read voltages; wherein an M-th first initial read voltage in the 2^{N-1}−1 first initial read voltages is less than an M-th second initial read voltage in the 2^{N-1}−1 second initial read voltages, and the M-th first initial read voltage in the 2^{N-1}−1 first initial read voltages is greater than an M−1th second initial read voltage in the 2^{N-1}−1 second initial read voltages, wherein M is an integer greater than 1.

In some examples, referring to FIG. 7, the first set of read voltages includes seven first initial read voltages, namely Va1 to Va7; the second set of read voltages includes seven second initial read voltages, namely Vb1 to Vb7, and the first initial read voltages and the second initial read voltages are alternately arranged in order of magnitude.

In some examples, the process of executing Operation S10 may include: performing 2^{N-1}−1 sets of first read operations on the multiple target memory cells based on the first set of read voltages, to obtain the first set of read results; wherein read voltages of each of the 2^{N-1}−1 sets of first read operations include one of the first initial read voltages and multiple first compensation read voltages obtained based on the first initial read voltage and a compensation value. The process of executing Operation S30 may include: performing 2^{N-1}−1 sets of second read operations on the multiple target memory cells based on the second set of read voltages, to obtain the second set of read results; wherein read voltages of each of the 2^{N-1}−1 sets of second read operations include one of the second initial read voltages and multiple second compensation read voltages obtained based on the second initial read voltage and a compensation value.

Here, each set of first read operations may include multiple times of first read operations, each set of second read operations may include multiple times of second read operations, and the first and second read operations are both single level read (SLR) operations. Performing one time of first or second read operation includes reading multiple target memory cells using one read voltage.

In some examples, the threshold voltage distributions of the first set of memory cells includes 2^{N-1}−1 valleys, and each set of first read operations may direct to one valley thereof; the threshold voltage distributions of the second set of memory cells includes 2^{N-1}−1 valleys, and each set of second read operations may direct to one valley thereof.

In some examples, the process of executing operation S20 may include obtaining 2^{N-1}−1 different first read reference voltages in the first set of read reference voltages based on the first set of read results and inverted level indicators of the multiple target memory cells. The process of executing operation S40 may include obtaining 2^{N-1}−1 different second read reference voltages in the second set of read reference voltages based on the second set of read results and the level indicators of the multiple target memory cells.

In some examples, the 2^{N-1}−1 different first read reference voltages in the first set of read reference voltages and the 2^{N-1}−1 different second read reference voltages in the second set of read reference voltages may be obtained by a method of traversing the valleys. For example, the process of obtaining an X-th first read reference voltage of the 2^{N-1}−1 different first read reference voltages in the first set of read reference voltages may include: obtaining the number of memory cells that store a first value in the first set of memory cells, corresponding to each read voltage of the X-th set of first read operations, based on read results of the X-th set of first read operations in the 2^{N-1}−1 sets of first read operations and the inverted level indicators ~LI of the multiple target memory cells, wherein X is a positive integer; and calculating differences between the numbers of memory cells that store the first value in the first set of memory cells corresponding to two adjacent read voltages in the X-th set of first read operations, and determining the X-th first read reference voltage in the 2^{N-1}−1 different first read reference voltages based on a minimum difference. The process of obtaining a Y-th second read reference voltage of the 2^{N-1}−1 different second read reference voltages in the second set of read reference voltages may include: obtaining the number of memory cells that store the first value in the second set of memory cells, corresponding to each read voltage of the Y-th set of second read operations based on read results of the Y-th set of second read operations in the 2^{N-1}−1 sets of second read operations and the level indicators LI of the multiple target memory cells, wherein Y is a positive integer; and calculating differences between the numbers of memory cells that store the first value in the second set of memory cells corresponding to two adjacent read voltages in the Y-th set of second read operations, and determining the Y-th second read reference voltage in the 2^{N-1}−1 different second read reference voltages based on a minimum difference.

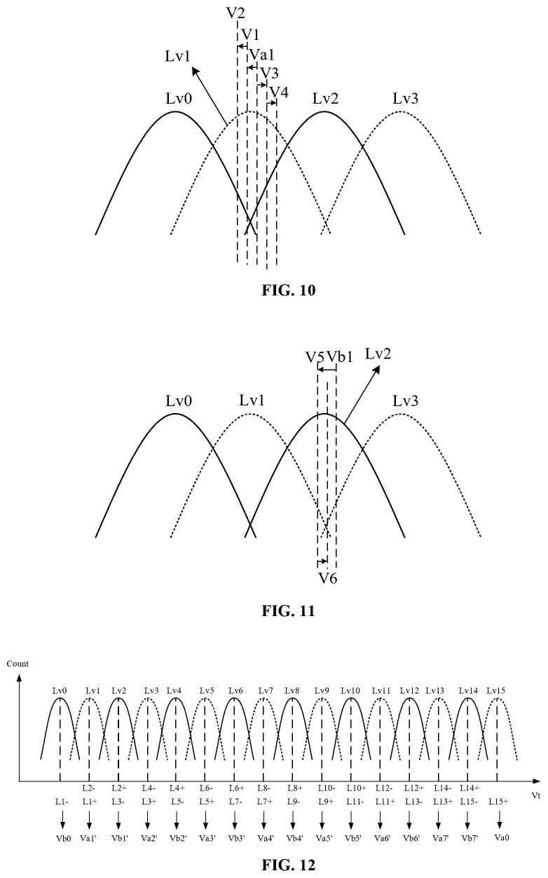

In an example, referring to FIGS. 9 and 10, taking a set of first read operations as an example, which direct to a first valley Valley0 of the threshold voltage distribution of the first set of memory cells, the read voltages of the set of first read operations include one of the first initial read voltages Va1 and multiple first compensation read voltages V1, V2, V3, and V4 obtained based on the first initial read voltage Va1 and a compensation value. Here, taking the compensation value being a fixed value as an example, that is, the differences between two adjacent read voltages are equal. The set of first read operations may include five times of the first read operations. That is, single-level read operations may be performed on multiple target memory cells with Va1, V1, V2, V3, and V4 as read voltages respectively, and then AND operations may be performed on the read result of each first read operation and the inverted level indicator ~LI of the multiple target cells, and the number of memory cells that store the first value corresponding to each read voltage (e.g., the number of memory cells that each store the first value in the first set of memory cells corresponding to each read voltage) after the AND operations is calculated. Here, the first value may be 1, and the number of memory cells that store the first value in the first set of memory cells corresponding to Va1, V1, V2, V3, and V4 may be counted as Ca, C1, C2, C3, and C4. Next, the differences between the numbers of memory cells that store the first value in the first set of memory cells corresponding to two adjacent read voltages may be calculated, namely Ca-C1, C1-C2, C3-Ca, and C4-C3, and the first read reference voltage is determined based on a minimum difference. For example, the minimum difference may be Ca-C1, then V1 would be the first read reference voltage obtained by the set of first read operations.

It should be noted that the number of first compensation read voltages, the magnitude of the compensation value, and the times of first read operations in each set of first read operations in the above examples are merely used as examples and not intended to put limitations on the operation method of the memory system provided in the present disclosure. Other first read reference voltages in the first set of read reference voltages may be obtained by the above method. In addition, 2^{N-1}−1 different second read reference voltages in the second set of read reference voltages may be obtained by a similar method. The main difference between the two methods is that when calculating the number of memory cells that store the first value in the second set of memory cells, the AND operations need to be performed on the read results of the second read operations and the level indicators LI of the multiple target memory cells, instead of the inverted level indicators ~LI of the multiple target memory cells.

It may be understood that based on the operation logic of an AND operation, when performing the first read operation, only for the memory cells in the first set of memory cells which read result is the first value, the result of an AND operation on its read result and the inverted level indicator ~LI would be the first value; and when performing the second read operation, only for the memory cells in the second set of memory cells which read result is the first value, the result of an AND operation on its read result and the level indicator LI is the first value. That is, the other set of memory cells may be excluded in the first and the second read operations by the inverted level indicator ~LI and the level indicator LI respectively, to achieve valley search for the threshold voltage distribution of the first set of memory cells and valley search for the threshold voltage distribution of the second set of memory cells.

In some examples, 2^{N-1}−1 different first read reference voltages in the first set of read reference voltages and 2^{N-1}−1 different second read reference voltages in the second set of read reference voltages may be obtained by a method of bisection. For example, the process of obtaining an X-th first read reference voltage of 2^{N-1}−1 different first read reference voltages in the first set of read reference voltages may include: obtaining the number of memory cells that store a first value in the first set of memory cells corresponding to each read voltage of the X-th set of first read operations based on read results of the X-th set of first read operations in the 2^{N-1}−1 sets of first read operations and the inverted level indicators of the multiple target memory cells; and calculating a ratio of the number of memory cells that store the first value in the first set of memory cells corresponding to each read voltage in the X-th set of first read operations to the number of memory cells in the first set of memory cells, and determining the X-th first read reference voltage in the 2^{N-1}−1 different first read reference voltages based on a comparison of the ratio and X×2^{1-N}. The process of obtaining a Y-th second read reference voltage of 2^{N-1}−1 different second read reference voltages in the second set of read reference voltages may include: obtaining the number of memory cells that store the first value in the second set of memory cells corresponding to each read voltage of the Y-th set of second read operations based on the read results of the Y-th set of second read operations in the 2^{N-1}−1 sets of second read operations and the level indicators of the multiple target memory cells; and calculating a ratio of the number of memory cells that store the first value in the second set of memory cells corresponding to each read voltage in the Y-th set of second read operations to the number of memory cells in the second set of memory cells, and determining the Y-th second read reference voltage in the 2^{N-1}−1 different second read reference voltages based on a comparison of the ratio and Y×2^{1-N}. In an example, referring to FIGS. 9 and 11, for example, Y equals to 1 and Y×2^{1-N} equals to ⅛, e.g., take obtaining a first second read reference voltage in the second set of read reference voltages by a first set of second read operations as an example. The read voltages of the set of second read operations include one of the second initial read voltages Vb1 and multiple second compensation read voltages V5 and V6 obtained based on the second initial read voltages Vb1 and a compensation value. For example, the second read operation may be performed with Vb1 as the read voltage, the AND operation may be performed on the read result and the level indicators LI of the multiple target cells, and the number of memory cells that store the first value may be calculated after the AND operation, that is, Cb, which is the number of memory cells that store the first value in the second set of memory cells corresponding to Vb1. The ratio of Cb to the total number Ct of memory cells in the second set of memory cells Cb/Ct may be compared with ⅛, if Cb/Ct is greater than ⅛, the compensation value may be subtracted from Vb1 to obtain a second compensation read voltage, and if Cb/Ct is less than ⅛, the compensation value may be added to Vb1 to obtain a second compensation read voltage. Here, as Cb/Ct is greater than ⅛, the compensation value is subtracted from Vb1 to obtain the second compensation read voltage V5. Then, a second read operation may be performed with V5 as the read voltage, and C5 may be obtained, which is the number of memory cells that store the first value in the second set of memory cells corresponding to V5. C5/Ct may be compared with ⅛, as C5/Ct is less than ⅛, the compensation value being ½ is added to V5 to obtain a second compensation read voltage V6. Then, a second read operation may be performed with V6 as the read voltage, and C6 which is the number of memory cells that store the first value in the second set of memory cells corresponding to V6 may be obtained, C6/Ct may be compared with ⅛. Here, C6/Ct is approximately equal to ⅛, then V6 is a second read reference voltage obtained by the set of second read operations.

It should be noted that the number of second compensation read voltages, the magnitude of compensation values, and the times of second read operations in each set of second read operations in the above examples are merely used as examples and not intended to put limitations on the operation method of the memory system provided in the present disclosure. Other second read reference voltages in the second set of read reference voltages may be obtained by the above method. In addition, 2^{N-1}−1 different first read reference voltages in the first set of read reference voltages may be obtained by a similar method. The main difference between the two methods is that when calculating the number of memory cells that store the first value in the first set of memory cells, the AND operations need to be performed on the read results of the first read operations and the inverted level indicators ~LI of the multiple target memory cells, instead of the level indicators LI of the multiple target memory cells.

In some examples, the first read operation and the second read operation may be alternately performed in groups, that is, a set of first read operations may be performed first to determine a first read reference voltage, and then a set of second read operations may be performed to determine a second read reference voltage, and so on, until the 2^{N-1}−1 sets of first read operations and the 2^{N-1}−1 sets of second read operations are completed. In other examples, the 2^{N-1}−1 sets of first read operations may be performed first, followed by the 2^{N-1}−1 sets of second read operations.

In some examples, after obtaining the first set of read reference voltages and the second set of read reference voltages based on the above method, operation S50 may be executed, by performing a plurality of third read operations on the multiple target memory cells based on the first set of read reference voltages and the second set of read reference voltages, to obtain a third set of read results.

In some examples, the process of executing operation S50 may include: using a first default read voltage of the first set of memory cells, a last default read voltage of the second set of memory cells, the first set of read reference voltages, and the second set of read reference voltages as a third set of read voltages; the first default read voltage of the first set of memory cells is less than a minimum first initial read voltage of the 2^{N-1}−1 first initial read voltages; the last default read voltage of the second set of memory cells is greater than a maximum second initial read voltage of the 2^{N-1}−1 second initial read voltages; and performing N sets of third read operations on the multiple target memory cells based on the third set of read voltages, to obtain the third set of read results.

In some examples, referring to FIGS. 7 and 12, the third set of read voltages includes a first default read voltage Vb0 of the first set of memory cells, a last default read voltage Va0 of the second set of memory cells, the first set of read reference voltages ‘Va1’ to ‘Va7’, and the second set of read reference voltages ‘Vb1’ to ‘Vb7’, wherein the first default read voltage Vb0 of the first set of memory cells is less than the minimum first initial read voltage Va1 of the seven first initial read voltages, and the last default read voltage Va0 of the second set of memory cells is greater than the maximum second initial read voltage Vb7 of the seven second initial read voltages.

In some examples, performing each set of third read operations includes: performing a first sub-read operation, to obtain a first sub-read result, wherein a read voltage of the first sub-read operation includes at least one first read reference voltage; and performing a second sub-read operation, to obtain a second sub-read result, wherein a read voltage of the second sub-read operation includes at least one second read reference voltage.

In some examples, the operation method of the memory system further comprises: obtaining data stored in the multiple target memory cells based on the third set of read results and the level indicators of the multiple target memory cells. For example, one-bit data of the N bits of data stored in each target memory cell may be obtained based on an operation result of the first sub-read result and the inverted level indicator ~LI of the multiple target memory cells and an operation result of the second sub-read result and the level indicator of the multiple target memory cells.

In some examples, referring to FIGS. 8 and 12, the process of executing operation S50 may include: performing four sets of third read operations on the multiple target memory cells based on the third set of read voltages, to obtain the third set of read results. The four sets of third read operations may read data of LP, MP, UP, and XP, respectively. Taking reading data of LP as an example, the read voltages of the first sub-read operation may include three first read reference voltages Va2′, Va3′, and Va5′, corresponding to L4−, L6−, and L10−, respectively; the read voltages of the second sub-read operation may include three second read reference voltages Vb2′, Vb3′, and Vb5′, corresponding to L4+, L6+, and L10+, respectively. The AND operation may be performed on the first sub-read results and the inverted level indicators ~LI of the multiple target memory cells, and the AND operation may be performed on the second sub-read results and the level indicators LI of the multiple target memory cells. Then, the data belongs to LP in four bits of data stored in each target memory cell may be obtained by adding the results of the two AND operations.

Similarly, when reading data of MP, the read voltages of the first sub-read operation may include four first read reference voltages Va1′, Va4′, Va5′, and Va6′, corresponding to L2−, L7+, L9+, and L12−, respectively; the read voltages of the second sub-read operation may include four second read reference voltages Vb1′, Vb3′, Vb4′, and Vb6′, corresponding to L2+, L7−, L9−, and L12+, respectively. When reading data of UP, the read voltages of the first sub-read operation may include three first read reference voltages Va3′, Va6′, and Va7′, corresponding to L5+, L11+, and L13+, respectively, and the default read voltage Va0 corresponding to L15+; the read voltages of the second sub-read operation may include four second read reference voltages Vb2′, Vb5′, Vb6′, and Vb7′, corresponding to L5−, L11−, L13−, and L15−, respectively. When reading data of XP, the read voltages of the first sub-read operation may include four first read reference voltages Va1′, Va2′, Va4′, and Va7′, corresponding to L1+, L3+, L8−, and L14−, respectively; the read voltages of the second sub read operation may include three second read reference voltages Vb1′, Vb4′, and Vb7′, corresponding to L3−, L8+, and L14+, respectively, and the default read voltage Vb0 corresponding to L1−.

It should be noted that the read voltages of each set of third read operations in the above example may be selected based on the encoding method shown in FIG. 8. In other examples, encoding methods different from FIG. 8 may be used for encoding data stored in multiple target memory cells, and the read voltages of the third read operation would vary based on the different encoding methods.

In an example of the present disclosure, the operation method of the memory system comprises a valley search method adapted to a level indicator. For example, multiple target memory cells may be divided into a first set of memory cells and a second set of memory cells using the level indicator, and valley search may be performed to the threshold voltage distributions of the first set of memory cells and the threshold voltage distributions of the second set of memory cells respectively, to obtain a first set of read reference voltages and a second set of read reference voltages. Furthermore, read operations may be performed on the multiple target memory cells based on the first set of read reference voltages and the second set of read reference voltages, and operations may be performed on the read results by the level indicator to obtain N bits of data stored in the multiple target memory cells. Thus, the reliability of reading data by the level indicator may be further improved, and the readable life of coarse programmed data may be extended.

Based on a concept similar to the operation method of the aforementioned memory system, the present disclosure further provides a memory device. Referring to FIGS. 4 and 5, the memory device 300 includes a memory array 301 and a peripheral circuit 302 coupled to the memory array 301. The memory array 301 includes multiple memory cells 305. The peripheral circuit 302 is configured to: perform a plurality of first read operations on multiple target memory cells of the multiple memory cells 305 based on a first set of read voltages, to obtain a first set of read results; perform a plurality of second read operations on the multiple target memory cells based on a second set of read voltages, to obtain a second set of read results; and perform a plurality of third read operations on the multiple target memory cells based on a first set of read reference voltages and a second set of read reference voltages, to obtain a third set of read results, wherein the first set of read reference voltages is obtained based on the first set of read results and level indicators of the multiple target memory cells; and the second set of read reference voltages is obtained based on the second set of read results and the level indicators of the multiple target memory cells.

In some examples, any one of the multiple target memory cells stores N bits of data, wherein N is an integer greater than 1; and a level indicator of each target memory cell is obtained based on the N bits of data stored in each target memory cell; the multiple target memory cells include a first set of memory cells that store 2^{N-1} different types of data and a second set of memory cells that store 2^{N-1} different types of data, wherein the level indicator of the first set of memory cells is different from the level indicator of the second set of memory cells.

In some examples, the peripheral circuit 302 is configured to: perform 2^{N-1}−1 sets of first read operations on the multiple target memory cells based on the first set of read voltages, to obtain the first set of read results, wherein read voltages of each first read operation of the 2^{N-1}−1 sets of first read operations include one first initial read voltage and multiple first compensation read voltages obtained based on the first initial read voltage and a compensation value; and perform 2^{N-1}−1 sets of second read operations on the multiple target memory cells based on the second set of read voltages, to obtain the second set of read results, wherein read voltages of each second read operation of the 2^{N-1}−1 sets of second read operations include one second initial read voltage and multiple second compensation read voltages obtained based on the second initial read voltages and the compensation value.

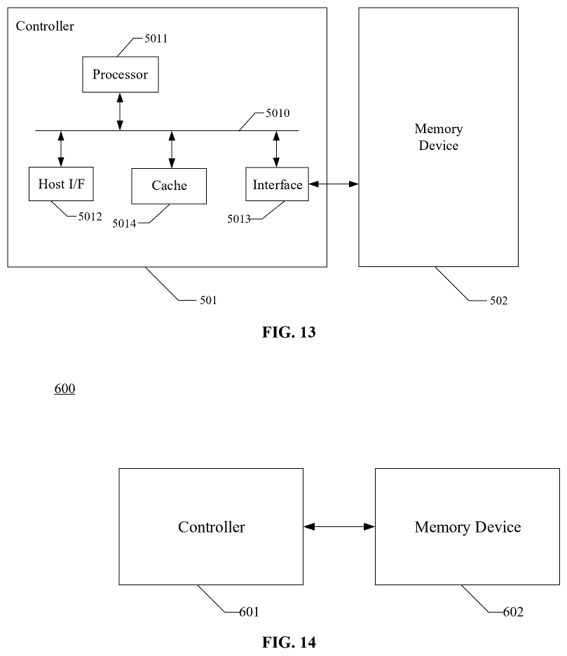

Based on a concept similar to the operation method of the aforementioned memory system, the present disclosure further provides a controller. Referring to FIG. 13, the controller 501 includes a processor 5011 and an interface 5013, the interface 5013 is coupled to at least one memory device 502.

In some examples, the memory device 502 may be the memory device 300 in the above examples.

In some examples, referring to FIG. 13, the controller 501 further includes a host interface 5012 and a cache 5014. The processor 5011 may be coupled to the host interface 5012, the cache 5014, and the interface 5013 through a bus 5010 and control the host interface 5012, the cache 5014, and the interface 5013.

In some examples, the processor 5011 is configured to: transmit a first read command and a second read command through the interface 5013, wherein the first read command instructs to perform first read operations on multiple target memory cells with a first set of read voltages, and the second read command instructs to perform second read operations on the multiple target memory cells with a second set of read voltages; obtain a first set of read reference voltages based on a first set of read results of the first read operations and the level indicators of the multiple target memory cells; obtain a second set of read reference voltages based on a second set of read results of the second read operations and the level indicators of the multiple memory cells; and transmit a third read command through the interface 5013, wherein the third read command instructs to perform third read operations on the multiple target memory cells with the first set of read reference voltages and the second set of read reference voltages.

In some examples, the processor 5011 is further configured to obtain data stored in the multiple target memory cells based on a third set of read results of the third read operations and the level indicators of the multiple target memory cells.

In some examples, the processor 5011 is further configured to obtain a level indicator of each target memory cell based on N bits of data stored in each target memory cell, wherein the multiple target memory cells include a first set of memory cells that store 2^{N-1} different types of data and a second set of memory cells that store 2^{N-1} different types of data, and the level indicator of the first set of memory cells is different from the level indicator of the second set of memory cells.

In some examples, the processor 5011 is further configured to: acquire 2^{N-1}−1 default read voltages of the second set of memory cells as 2^{N-1}−1 first initial read voltages in the first set of read voltages; and acquire 2^{N-1}−1 default read voltages of the first set of memory cells as 2^{N-1}−1 second initial read voltages in the second set of read voltages, wherein an M-th first initial read voltage in the 2^{N-1}−1 first initial read voltages is less than an M-th second initial read voltage in the 2^{N-1}−1 second initial read voltages, and the M-th first initial read voltage in the 2^{N-1}−1 first initial read voltages is greater than the (M−1)-th second initial read voltage in the 2^{N-1}−1 second initial read voltages, wherein M is an integer greater than 1.

In some examples, the processor 5011 is further configured to: obtain multiple different first compensation read voltages in the first set of read voltages based on the 2^{N-1}−1 first initial read voltages and a compensation value; and obtain multiple different second compensation read voltages in the second set of read voltages based on the 2^{N-1}−1 second initial read voltages and a compensation value.

In some examples, the processor 5011 is configured to: obtain 2^{N-1}−1 different first read reference voltages in the first set of read reference voltages based on the first set of read results and inverted level indicators of the multiple target memory cells; and obtain 2^{N-1}−1 different second read reference voltages in the second set of read reference voltages based on the second set of read results and the level indicators of the multiple target memory cells.

In some examples, parameters such as level indicator, default read voltages of the first set of memory cells, and default read voltages of the second set of memory cells may be stored in the cache 5014.

Based on a concept similar to the operation method of the aforementioned memory system, the present disclosure further provides a memory system. Referring to FIG. 14, the memory system 600 includes a memory device 602 and a controller 601 coupled to the memory device 602.

In some examples, the memory device 602 may be the memory device 300 provided in the above examples, and the controller 601 may be the controller 501 provided in the above examples.

In some examples, the controller 601 is configured to transmit a first read command and a second read command, wherein the first read command instructs to perform first read operations on multiple target memory cells in the memory device with a first set of read voltages, and the second read command instructs to perform second read operations on the multiple target memory cells with a second set of read voltages.

The memory device 602 is configured to: in response to the first read command, perform a plurality of the first read operations on the multiple target memory cells based on the first set of read voltages, to obtain a first set of read results, and transmit the first set of read results; and in response to the second read command, perform a plurality of the second read operations on the multiple target memory cells based on the second set of read voltages, to obtain a second set of read results, and transmit the second set of read results.

The controller 601 is further configured to: obtain a first set of read reference voltages based on the first set of read results and level indicators of the multiple target memory cells; obtain a second set of read reference voltages based on the second set of read results and the level indicators of the multiple target memory cells; and transmit a third read command, wherein the third read command instructs third read operations on the multiple target memory cells with the first set of read reference voltages and the second set of read reference voltages.

The memory device 602 is further configured to: in response to the third read command, perform a plurality of the third read operations on the multiple target memory cells based on the first set of read reference voltages and the second set of read reference voltages, to obtain a third set of read results, and transmit the third set of read results.

In some examples, the controller 601 is further configured to obtain data stored in the multiple target memory cells based on the third set of read results and the level indicators of the multiple target memory cells.

In some examples, any one of the multiple target memory cells stores N bits of data, wherein N is an integer greater than 1; and the controller 601 is further configured to: obtain a level indicator of each target memory cell based on the N bits of data stored in each target memory cell, wherein the multiple target memory cells include a first set of memory cells that store 2^{N-1} different types of data and a second set of memory cells that store 2^{N-1} different types of data, and the level indicator of the first set of memory cells is different from the level indicator of the second set of memory cells.

In some examples, the controller 601 is further configured to: acquire 2^{N-1}−1 default read voltages of the second set of memory cells as 2^{N-1}−1 first initial read voltages in the first set of read voltages; and acquire 2^{N-1}−1 default read voltages of the first set of memory cells as 2^{N-1}−1 second initial read voltages in the second set of read voltages, wherein an M-th first initial read voltage in the 2^{N-1}−1 first initial read voltages is less than an M-th second initial read voltage in the 2^{N-1}−1 second initial read voltages, and the M-th first initial read voltage in the 2^{N-1}−1 first initial read voltages is greater than an (M−1)th second initial read voltage in the 2^{N-1}−1 second initial read voltages, wherein M is an integer greater than 1.

In some examples, the memory device 602 is specifically configured to: in response to the first read command, perform 2^{N-1}−1 sets of first read operations on the multiple target memory cells based on the first set of read voltages, to obtain the first set of read results, wherein read voltages of each set of the 2^{N-1}−1 sets of first read operations include one first initial read voltage and multiple first compensation read voltages obtained based on the first initial read voltages and a compensation value; and in response to the second read command, perform 2^{N-1}−1 sets of second read operations on the multiple target memory cells based on the second set of read voltages, to obtain the second set of read results, wherein read voltages of each set of the 2^{N-1}−1 sets of second read operations include one second initial read voltage and multiple second compensation read voltages obtained based on the second initial read voltages and the compensation value.

In some examples, the controller 601 is configured to: obtain 2^{N-1}−1 different first read reference voltages in the first set of read reference voltages based on the first set of read results and inverted level indicators of the multiple target memory cells; and obtain 2^{N-1}−1 different second read reference voltages in the second set of read reference voltages based on the second set of read results and the level indicators of the multiple target memory cells.

It should be noted that the memory system 600 could implement the operation method of the memory system provided in any of the above examples. The effects that may be achieved by the operation method of the memory system provided in any of the above examples may be achieved by the memory system, and will not be repeated here.

Based on a concept similar to the operation method of the aforementioned memory system, the present disclosure further provides a system comprising a memory array and a control circuit coupled to the memory array.

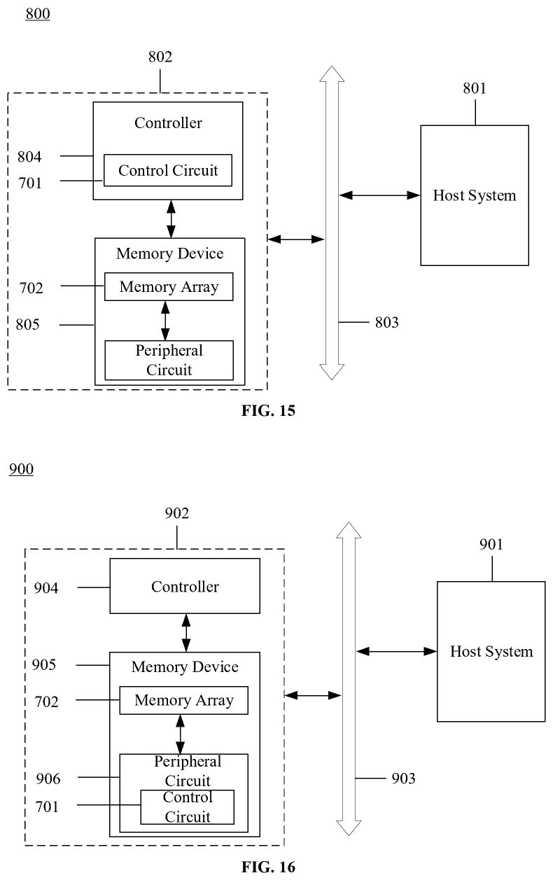

In some examples, referring to FIG. 15, a system 800 includes a host system 801 and a memory system 802 coupled to the host system 801 through a bus 803. The memory system 802 includes a memory device 805 and a controller 804 coupled to the memory device 805. A memory array 702 is located in the memory device 805, and a control circuit 701 is located in the controller 804.

In some examples, referring to FIG. 16, a system 900 includes a host system 901 and a memory system 902 coupled to the host system 901 through a bus 903. The memory system 902 includes: a memory device 905 and a controller 904 coupled to the memory device 905. The memory device 905 includes a memory array 702 and a peripheral circuit 906 coupled to the memory array 702. The control circuit 701 is located in the peripheral circuit 906.

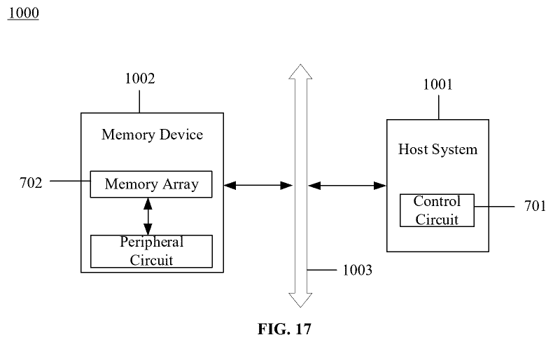

In some examples, referring to FIG. 17, a system 1000 includes a host system 1001 and a memory device 1002 coupled to the host system 1001 through a bus 1003. The memory array 702 is located in the memory device 1002, and the control circuit 701 is located in the host system 1001.

In some examples, the control circuit 701 may be configured to perform the operation method of the memory system provided by any of the above examples.

In some examples, the control circuit 701 is configured to: perform a plurality of first read operations on multiple target memory cells based on a first set of read voltages, to obtain a first set of read results; obtain a first set of read reference voltages based on the first set of read results and level indicators of the multiple target memory cells; perform a plurality of second read operations on the multiple target memory cells based on a second set of read voltages, to obtain a second set of read results; obtain a second set of read reference voltages based on the second set of read results and the level indicators of the multiple target memory cells; and perform a plurality of third read operations on the multiple target memory cells based on the first set of read reference voltages and the second set of read reference voltages, to obtain a third set of read results.

In some examples, the control circuit 701 is further configured to obtain data stored in the multiple target memory cells based on the third set of read results and the level indicators of the multiple target memory cells.

In some examples, any one of the multiple target memory cells stores N bits of data, wherein N is an integer greater than 1. The control circuit 701 is further configured to: obtain a level indicator of each target memory cell based on the N bits of data stored in each target memory cell, wherein the multiple target memory cells include a first set of memory cells that store 2^{N-1} different types of data and a second set of memory cells that store 2^{N-1} different types of data, and the level indicator of the first set of memory cells is different from the level indicator of the second set of memory cells.

In some examples, the control circuit 701 is further configured to: acquire 2^{N-1}−1 default read voltages of the second set of memory cells as 2^{N-1}−1 first initial read voltages in the first set of read voltages; and acquire 2^{N-1}−1 default read voltages of the first set of memory cells as 2^{N-1}−1 second initial read voltages in the second set of read voltages, wherein an M-th first initial read voltage in the 2^{N-1}−1 first initial read voltages is less than an M-th second initial read voltage in the 2^{N-1}−1 second initial read voltages, and the M-th first initial read voltage in the 2^{N-1}−1 first initial read voltages is greater than an (M−1)th second initial read voltage in the 2^{N-1}−1 second initial read voltages, wherein M is an integer greater than 1.

In some examples, the control circuit 701 is configured to perform 2^{N-1}−1 sets of first read operations on the multiple target memory cells based on the first set of read voltages, to obtain the first set of read results, wherein read voltages of each set of the 2^{N-1}−1 sets of first read operations include one first initial read voltage and multiple first compensation read voltages obtained based on the first initial read voltages and a compensation value; and perform 2^{N-1}−1 sets of second read operations on the multiple target memory cells based on the second set of read voltages, to obtain the second set of read results, wherein read voltages of each set of the 2^{N-1}−1 sets of second read operations include one second initial read voltage and multiple second compensation read voltages obtained based on the second initial read voltages and the compensation value.

In some examples, the control circuit 701 is configured to: obtain 2^{N-1}−1 different first read reference voltages in the first set of read reference voltages based on the first set of read results and inverted level indicators of the multiple target memory cells; and obtain 2^{N-1}−1 different second read reference voltages in the second set of read reference voltages based on the second set of read results and the level indicators of the multiple target memory cells.

It should be noted that the system provided in an example of the present disclosure can implement the operation method of the memory system provided in any of the above examples. The effects that may be achieved by the operation method of the memory system provided in any of the above examples may be achieved by the system, and will not be repeated here.

Based on a concept similar to the operation method of the above memory system, the present disclosure further provides a non-transitory computer-readable storage medium storing executable instructions thereon that, when executed by the memory system, can implement the operation method of the memory system in any of the above examples of the present disclosure.

In some examples, a non-transitory computer-readable storage medium may be ferromagnetic random access memory (FRAM), read only memory (ROM), programmable read only memory (PROM), erasable programmable read only memory (EPROM), electrically erasable programmable read only memory (EEPROM), flash memory, magnetic surface memory, disc, or compact disc read only memory (CD-ROM), etc.; or various devices including one or any combination of the above-mentioned memory devices.

In some examples, executable instructions may be in the form of programs, software, software modules, scripts, or code, written in any form of programming language (including compiled or interpreted languages, or declarative or procedural languages), and may be deployed in any form, including as standalone programs or as modules, components, subroutines, or other units suitable for use in a computing environment.

As an example, executable instructions may not necessarily correspond to files in a file system, and may be stored as part of a file that stores other programs or data, for example, stored in one or more scripts in a Hyper Text Markup Language (HTML) document, in a single file dedicated to the discussed program, or in multiple collaborative files (such as files that store one or more modules, subroutines, or code parts).

As an example, executable instructions may be deployed to be executed on a memory system, or on multiple electronic devices located in one location, or on multiple electronic devices distributed across multiple locations and interconnected through a communication network.

The methods disclosed in the example methods provided in the present disclosure may be combined arbitrarily without conflict to obtain a new method example.

The features disclosed in the example devices provided in the present disclosure may be combined arbitrarily without conflict to obtain a new device example.

Examples of the present disclosure provide a memory system and an operation method, a controller, a memory device, a system, and non-transitory computer-readable storage medium thereof.

In a first aspect, the present disclosure provides an operation method of a memory system, comprising: performing a plurality of first read operations on multiple target memory cells based on a first set of read voltages, to obtain a first set of read results; obtaining a first set of read reference voltages based on the first set of read results and level indicators of the multiple target memory cells; performing a plurality of second read operations on the multiple target memory cells based on a second set of read voltages, to obtain a second set of read results; obtaining a second set of read reference voltages based on the second set of read results and level indicators of the multiple target memory cells; and performing a plurality of third read operations on the multiple target memory cells based on the first set of read reference voltages and the second set of read reference voltages, to obtain a third set of read results.

In an optional example, the operation method of the memory system further comprises: obtaining data stored in the multiple target memory cells based on the third set of read results and level indicators of the multiple target memory cells.

In an optional example, any one of the multiple target memory cells stores N bits of data, wherein N is an integer greater than 1; and the operation method of the memory system further comprises: obtaining a level indicator of each target memory cell based on the N bits of data stored in each target memory cell, wherein the multiple target memory cells include a first set of memory cells that store 2^{N-1} different types of data and a second set of memory cells that store 2^{N-1} different types of data; and a level indicator of the first set of memory cells is different from a level indicator of the second set of memory cells.

In an optional example, the operation method of the memory system further comprises: acquiring 2^{N-1}−1 default read voltages of the second set of memory cells as 2^{N-1}−1 first initial read voltages in the first set of read voltages; and acquiring 2^{N-1}−1 default read voltages of the first set of memory cells as 2^{N-1}−1 second initial read voltages in the second set of read voltages, wherein an M-th first initial read voltage in the 2^{N-1}−1 first initial read voltages is less than an M-th second initial read voltage in the 2^{N-1}−1 second initial read voltages, and an M-th first initial read voltage in the 2^{N-1}−1 first initial read voltages is greater than an (M−1)th second initial read voltage in the 2^{N-1}−1 second initial read voltages; wherein M is an integer greater than 1.

In an optional example, the first read operation and the second read operation are both a single-level read operation.

In an optional example, the performing a plurality of first read operations on multiple target memory cells based on a first set of read voltages to obtain a first set of read results comprises: performing 2^{N-1}−1 sets of first read operations on the multiple target memory cells based on the first set of read voltages, to obtain the first set of read results, wherein read voltages of each set of the 2^{N-1}−1 sets of first read operations include one first initial read voltage and multiple first compensation read voltages obtained based on the first initial read voltage and a compensation value; and the performing a plurality of second read operations on multiple target memory cells based on a second set of read voltages to obtain a second set of read results comprises: performing 2^{N-1}−1 sets of second read operations on the multiple target memory cells based on the second set of read voltages, to obtain the second set of read results, wherein read voltages of each set of the 2^{N-1}−1 sets of second read operations include one second initial read voltage and multiple second compensation read voltages obtained based on the second initial read voltages and the compensation value.

In an optional example, the obtaining a first set of read reference voltages based on the first set of read results and level indicators of the multiple target memory cells comprises: obtaining 2^{N-1}−1 different first read reference voltages in the first set of read reference voltages based on the first set of read results and inverted level indicators of the multiple target memory cells; and the obtaining a second set of read reference voltages based on the second set of read results and the level indicators of the multiple target memory cells comprises: obtaining 2^{N-1}−1 different second read reference voltages in the second set of read reference voltages based on the second set of read results and the level indicators of the multiple target memory cells.

In an optional example, the obtaining 2^{N-1}−1 different first read reference voltages in the first set of read reference voltages based on the first set of read results and inverted level indicators of the multiple target memory cells comprises: obtaining the number of memory cells that store a first value in the first set of memory cells corresponding to each read voltage of an X-th set of first read operations in the 2^{N-1}−1 set of first read operations based on read results of the X-th set of first read operations and inverted level indicators of the multiple target memory cells, wherein X is a positive integer; and calculating differences between the numbers of memory cells that store the first value in the first set of memory cells corresponding to two adjacent read voltages in the X-th set of first read operations, and determining the X-th first read reference voltage in the 2^{N-1}−1 different first read reference voltages based on a minimum of the differences; or, calculating a ratio of the number of memory cells that store the first value in the first set of memory cells corresponding to each read voltage in the X-th set of first read operations to the number of memory cells in the first set of memory cells, and determining the X-th first read reference voltage in the 2^{N-1}−1 different first read reference voltages based on a comparison of the ratio and X×2^{1-N}.

In an optional example, the obtaining 2^{N-1}−1 different second read reference voltages in the second set of read reference voltages based on the second set of read results and level indicators of the multiple target memory cells comprises: obtaining the number of memory cells that store a first value in the second set of memory cells corresponding to each read voltage of a Y-th set of second read operations in the 2^{N-1}−1 sets of second read operations based on the read results of the Y-th set of second read operations and level indicators of the multiple target memory cells, wherein Y is a positive integer; and calculating differences between the numbers of memory cells that store a first value in the second set of memory cells corresponding to two adjacent read voltages in the Y-th set of second read operations, and determining the Y-th second read reference voltage in the 2^{N-1}−1 different second read reference voltages based on a minimum of the differences; or, calculating a ratio of the number of memory cells that store a first value in the second set of memory cells corresponding to each read voltage in the Y-th set of second read operations to the number of memory cells in the second set of memory cells, and determining the Y-th second read reference voltage in the 2^{N-1}−1 different second read reference voltages based on a comparison of the ratio and Y×2^{1-N}.

In an optional example, the performing a plurality of third read operations on the multiple target memory cells based on the first set of read reference voltages and the second set of read reference voltages to obtain a third set of read results comprises: using a first default read voltage of the first set of memory cells, a last default read voltage of the second set of memory cells, the first set of read reference voltages and the second set of read reference voltages as a third set of read voltages, wherein the first default read voltage of the first set of memory cells is less than a minimum first initial read voltage of the 2^{N-1}−1 first initial read voltages; and the last default read voltage of the second set of memory cells is greater than a maximum second initial read voltage of the 2^{N-1}−1 second initial read voltages; and performing N sets of third read operations on the multiple target memory cells based on the third set of read voltages, to obtain the third set of read results.

In an optional example, performing each set of third read operations comprises: performing a first sub-read operation, to obtain a first sub-read result, wherein a read voltage of the first sub-read operation includes at least one of the first read reference voltages; performing a second sub-read operation, to obtain a second sub-read result, wherein a read voltage of the second sub read operation includes at least one of the second read reference voltages; and the obtaining data stored in the multiple target memory cells based on the third set of read results and level indicators of the multiple target memory cells comprises: obtaining one bit of data in the N bits of data stored in each target memory cell based on an operation result of the first sub-read result and inverted level indicators of the multiple target memory cells and an operation result of the second sub-read result and level indicators of the multiple target memory cells.

In a second aspect, the present disclosure provides a memory device, comprising a memory array and a peripheral circuit coupled to the memory array, wherein the memory array comprises multiple memory cells; and the peripheral circuit is configured to: perform a plurality of first read operations on multiple target memory cells of the multiple memory cells based on a first set of read voltages, to obtain a first set of read results; perform a plurality of second read operations on the multiple target memory cells based on a second set of read voltages, to obtain a second set of read results; and perform a plurality of third read operations on the multiple target memory cells based on a first set of read reference voltages and a second set of read reference voltages, to obtain a third set of read results, wherein the first set of read reference voltages is obtained based on the first set of read results and level indicators of the multiple target memory cells; and the second set of read reference voltages is obtained based on the second set of read results and the level indicators of the multiple target memory cells.

In an optional example, any one multiple target memory cell of the multiple target memory cells stores N bits of data, wherein N is an integer greater than 1; and a level indicator of each target memory cell is obtained based on the N bits of data stored in each target memory cell; the multiple target memory cells include a first set of memory cells that store 2^{N-1} different types of data and a second set of memory cells that store 2^{N-1} different types of data; and a level indicator of the first set of memory cells is different from a level indicator of the second set of memory cells.

In an optional example, the peripheral circuit is configured to: perform 2^{N-1}−1 sets of first read operations on the multiple target memory cells based on the first set of read voltages, to obtain the first set of read results, wherein read voltages of each set of the 2^{N-1}−1 sets of first read operations include one first initial read voltage and multiple first compensation read voltages obtained based on the first initial read voltage and a compensation value; and perform 2^{N-1}−1 sets of second read operations on the multiple target memory cells based on the second set of read voltages, to obtain the second set of read results, wherein read voltages of each set of the 2^{N-1}−1 sets of second read operations include one second initial read voltage and multiple second compensation read voltages obtained based on the second initial read voltage and the compensation value.

In a third aspect, the present disclosure provides a controller, comprising a processor and an interface coupled to at least one memory device, wherein the processor is configured to: transmit a first read command and a second read command through the interface, wherein the first read command instructs to perform first read operations on multiple target memory cells with a first set of read voltages; and the second read command instructs to perform second read operations on the multiple target memory cells with a second set of read voltages; obtain a first set of read reference voltages based on a first set of read results of the first read operations and level indicators of the multiple target memory cells; and obtain a second set of read reference voltages based on a second set of read results of the second read operations and a level indicator of the multiple memory cells; and transmit a third read command through the interface, wherein the third read command instructs to perform third read operations on the multiple target memory cells with the first set of read reference voltages and the second set of read reference voltages.

In an optional example, the processor is further configured to: obtain data stored in the multiple target memory cells based on a third set of read results of the third read operations and level indicators of the multiple target memory cells.

In an optional example, the processor is further configured to: obtain a level indicator of each target memory cell based on N bits of data stored in each target memory cell, wherein the multiple target memory cells include a first set of memory cells that store 2^{N-1} different types of data and a second set of memory cells that store 2^{N-1} different types of data; and a level indicator of the first set of memory cells is different from a level indicator of the second set of memory cells.

In an optional example, the processor is further configured to: acquire 2^{N-1}−1 default read voltages of the second set of memory cells as 2^{N-1}−1 first initial read voltages in the first set of read voltages; and acquire 2^{N-1}−1 default read voltages of the first set of memory cells as 2^{N-1}−1 second initial read voltages in the second set of read voltages, wherein an M-th first initial read voltage in the 2^{N-1}−1 first initial read voltages is less than an M-th second initial read voltage in the 2^{N-1}−1 second initial read voltages, and an M-th first initial read voltage in the 2^{N-1}−1 first initial read voltages is greater than a (M−1)th second initial read voltage in the 2^{N-1}−1 second initial read voltages, wherein M is an integer greater than 1.

In an optional example, the processor is further configured to: obtain multiple different first compensation read voltages in the first set of read voltages based on the 2^{N-1}−1 first initial read voltages and a compensation value; and obtain multiple different second compensation read voltages in the second set of read voltages based on the 2^{N-1}−1 second initial read voltages and the compensation value.

In an optional example, the processor is configured to: obtain 2^{N-1}−1 different first read reference voltages in the first set of read reference voltages based on the first set of read results and inverted level indicators of the multiple target memory cells; and obtain 2^{N-1}−1 different second read reference voltages in the second set of read reference voltages based on the second set of read results and level indicators of the multiple target memory cells.

In a fourth aspect, the present disclosure provides a memory system, comprising a memory device and a controller coupled to the memory device, wherein the controller is configured to transmit a first read command and a second read command; the first read command instructs to perform first read operations on multiple target memory cells in the memory device with a first set of read voltages; and the second read command instructs to perform second read operations on the multiple target memory cells with a second set of read voltages. The memory device is configured to: in response to the first read command, perform a plurality of first read operations on the multiple target memory cells based on the first set of read voltages, to obtain a first set of read results, and transmit the first set of read results; and in response to the second read command, perform a plurality of second read operations on the multiple target memory cells based on the second set of read voltages, to obtain a second set of read results, and transmit the second set of read results. The controller is further configured to: obtain a first set of read reference voltages based on the first set of read results and level indicators of the multiple target memory cells; obtain a second set of read reference voltages based on the second set of read results and level indicators of the multiple target memory cells; and transmit a third read command, wherein the third read command instructs to perform third read operations on the multiple target memory cells with the first set of read reference voltages and the second set of read reference voltages. The memory device is further configured to: in response to the third read command, perform a plurality of third read operations on the multiple target memory cells based on the first set of read reference voltages and the second set of read reference voltages, to obtain a third set of read results, and transmit the third set of read results.

In an optional example, the controller is further configured to: obtain data stored in the multiple target memory cells based on the third set of read results and level indicators of the multiple target memory cells.

In an optional example, any one multiple target memory cell of the multiple target memory cells stores N bits of data, wherein N is an integer greater than 1; and the controller is further configured to: obtain a level indicator of each target memory cell based on the N bits of data stored in each target memory cell, wherein the multiple target memory cells include a first set of memory cells that store 2^{N-1} different types of data and a second set of memory cells that store 2^{N-1} different types of data; and a level indicator of the first set of memory cells is different from a level indicator of the second set of memory cells.

In an optional example, the controller is further configured to: acquire 2^{N-1}−1 default read voltages of the second set of memory cells as 2^{N-1}−1 first initial read voltages in the first set of read voltages; and acquire 2^{N-1}−1 default read voltages of the first set of memory cells as 2^{N-1}−1 second initial read voltages in the second set of read voltages, wherein an M-th first initial read voltage in the 2^{N-1}−1 first initial read voltages is less than an M-th second initial read voltage in the 2^{N-1}−1 second initial read voltages, and an M-th first initial read voltage in the 2^{N-1}−1 first initial read voltages is greater than a (M−1)th second initial read voltage in the 2^{N-1}−1 second initial read voltages, wherein M is an integer greater than 1.

In an optional example, the memory device is configured to: in response to the first read command, perform 2^{N-1}−1 sets of first read operations on the multiple target memory cells based on the first set of read voltages, to obtain the first set of read results, wherein read voltages of each set of the 2^{N-1}−1 sets of first read operations include one first initial read voltage and multiple first compensation read voltages obtained based on the first initial read voltage and a compensation value; and in response to the second read command, perform 2^{N-1}−1 sets of second read operations on the multiple target memory cells based on the second set of read voltages, to obtain the second set of read results, wherein read voltages of each set of the 2^{N-1}−1 sets of second read operations include one second initial read voltage and multiple second compensation read voltages obtained based on the second initial read voltage and the compensation value.

In an optional example, the controller is configured to: obtain 2^{N-1}−1 different first read reference voltages in the first set of read reference voltages based on the first set of read results and inverted level indicators of the multiple target memory cells; and obtain 2^{N-1}−1 different second read reference voltages in the second set of read reference voltages based on the second set of read results and level indicators of the multiple target memory cells.

In a fifth aspect, the present disclosure provides a system, comprising a memory array and a control circuit coupled to the memory array and configured to: perform a plurality of first read operations on multiple target memory cells based on a first set of read voltages, to obtain a first set of read results; obtain a first set of read reference voltages based on the first set of read results and level indicators of the multiple target memory cells; perform a plurality of second read operations on the multiple target memory cells based on a second set of read voltages, to obtain a second set of read results; obtain a second set of read reference voltages based on the second set of read results and level indicators of the multiple target memory cells; and perform a plurality of third read operations on the multiple target memory cells based on the first set of read reference voltages and the second set of read reference voltages, to obtain a third set of read results.

In an optional example, the control circuit is further configured to: obtain data stored in the multiple target memory cells based on the third set of read results and level indicators of the multiple target memory cells.

In an optional example, any one of the multiple target memory cells stores N bits of data, wherein N is an integer greater than 1; and the control circuit is further configured to: obtain a level indicator of each target memory cell based on the N bits of data stored in each target memory cell, wherein the multiple target memory cells include a first set of memory cells that store 2^{N-1} different types of data and a second set of memory cells that store 2^{N-1} different types of data; and a level indicator of the first set of memory cells is different from a level indicator of the second set of memory cells.

In an optional example, the control circuit is further configured to: acquire 2^{N-1}−1 default read voltages of the second set of memory cells as 2^{N-1}−1 first initial read voltages in the first set of read voltages; and acquire 2^{N-1}−1 default read voltages of the first set of memory cells as 2^{N-1}−1 second initial read voltages in the second set of read voltages, wherein an M-th first initial read voltage in the 2^{N-1}−1 first initial read voltages is less than an M-th second initial read voltage in the 2^{N-1}−1 second initial read voltages, and an M-th first initial read voltage in the 2^{N-1}−1 first initial read voltages is greater than a (M−1)th second initial read voltage in the 2^{N-1}−1 second initial read voltages, wherein M is an integer greater than 1.

In an optional example, the control circuit is configured to: perform 2^{N-1}−1 sets of first read operations on the multiple target memory cells based on the first set of read voltages, to obtain the first set of read results, wherein read voltages of each set of the 2^{N-1}−1 sets of first read operations include one first initial read voltage and multiple first compensation read voltages obtained based on the first initial read voltage and a compensation value; and

perform 2^{N-1}−1 sets of second read operations on the multiple target memory cells based on the second set of read voltages, to obtain the second set of read results, wherein read voltages of each set of the 2^{N-1}−1 sets of second read operations include one second initial read voltage and multiple second compensation read voltages obtained based on the second initial read voltage and the compensation value.

In an optional example, the control circuit is configured to: obtain 2^{N-1}−1 different first read reference voltages in the first set of read reference voltages based on the first set of read results and inverted level indicators of the multiple target memory cells; and
obtain 2^{N-1}−1 different second read reference voltages in the second set of read reference voltages based on the second set of read results and level indicators of the multiple target memory cells.

In an optional example, the system comprises: a memory device, and a controller coupled to the memory device, wherein the memory array is located in the memory device, and the control circuit is located in the controller.

In an optional example, the system comprises a memory device; and the memory device comprises the memory array and a peripheral circuit coupled to the memory array; and the control circuit is located in the peripheral circuit.

In an optional example, the system comprises: a memory device, and a host system coupled to the memory device; and the memory array is located in the memory device, and the control circuit is located in the host system.

In a sixth aspect, the present disclosure provides a non-transitory computer-readable storage medium storing a computer program that, when executed, can implement the operation method of the memory system of any of examples described above.

In the implementations provided in the present disclosure, the operation method of the memory system includes a valley search method adapted to a level indicator. For example, multiple target memory cells may be divided into a first set of memory cells and a second set of memory cells by a level indicator, and the valley search may be performed to threshold voltage distributions of the first set of memory cells and threshold voltage distributions of the second set of memory cells respectively, to obtain a first set of read reference voltages and a second set of read reference voltages respectively. Further, read operations may be performed on the multiple target memory cells based on the first set of read reference voltages and the second set of read reference voltages, and operations may be performed on read results with a level indicator to obtain N bits of data stored in the multiple target memory cells. Therefore, the reliability of using a level indicator for data reading may be further improved, and the readable life of the coarse programmed data may be extended.

The above are only implementations of the present disclosure, and the scope of the present disclosure is not limited to thereof. Any person skilled in the art may easily think of variations or replacements within the technical scope disclosed in the present disclosure, which should be included in the scope of the present disclosure.

What is claimed is:

1. A method of a memory system, the method comprising:
performing a plurality of first read operations on multiple target memory cells based on a first set of read voltages to obtain a first set of read results;
obtaining a first set of read reference voltages based on the first set of read results and level indicators of the multiple target memory cells;
performing a plurality of second read operations on the multiple target memory cells based on a second set of read voltages to obtain a second set of read results;
obtaining a second set of read reference voltages based on the second set of read results and level indicators of the multiple target memory cells; and
performing a plurality of third read operations on the multiple target memory cells based on the first set of read reference voltages and the second set of read reference voltages to obtain a third set of read results.

2. The method of the memory system of claim 1, further comprising:
obtaining data stored in the multiple target memory cells based on the third set of read results and level indicators of the multiple target memory cells.

3. The method of the memory system of claim 2, wherein any one of the multiple target memory cells stores N bits of data, and wherein N is an integer greater than 1, the method of the memory system further comprising:
obtaining a level indicator of each target memory cell based on the N bits of data stored in each target memory cell, wherein the multiple target memory cells include a first set of memory cells that store 2^{N-1} different types of data and a second set of memory cells that store 2^{N-1} different types of data, and wherein a level indicator of the first set of memory cells is different from a level indicator of the second set of memory cells.

4. The method of the memory system of claim 3, further comprising:
acquiring 2^{N-1}−1 default read voltages of the second set of memory cells as 2^{N-1}−1 first initial read voltages in the first set of read voltages; and
acquiring 2^{N-1}−1 default read voltages of the first set of memory cells as 2^{N-1}−1 second initial read voltages in the second set of read voltages, wherein an M-th first initial read voltage in the 2^{N-1}−1 first initial read voltages is less than an M-th second initial read voltage in the 2^{N-1}−1 second initial read voltages, and the M-th first initial read voltage in the 2^{N-1}−1 first initial read voltages is greater than an (M−1)th second initial read voltage in the 2^{N-1}−1 second initial read voltages, wherein M is an integer greater than 1.

5. The method of the memory system of claim 4, wherein each of the first read operations and the second read operations is a single-level read operation.

6. The method of the memory system of claim 5, wherein:
the performing of the plurality of first read operations on the multiple target memory cells based on the first set of read voltages to obtain the first set of read results comprises:
performing 2^{N-1}−1 sets of first read operations on the multiple target memory cells based on the first set of read voltages, to obtain the first set of read results, wherein read voltages of each set of the 2^{N-1}−1 sets of first read operations include one first initial read voltage and multiple first compensation read voltages obtained based on the first initial read voltage and a compensation value; and
the performing of the plurality of second read operations on the multiple target memory cells based on the second set of read voltages to obtain the second set of read results comprises:
performing 2^{N-1}−1 sets of second read operations on the multiple target memory cells based on the second set of read voltages, to obtain the second set of read results, wherein read voltages of each set of the 2^{N-1}−1 sets of second read operations include one second initial read voltage and multiple second compensation read voltages obtained based on the second initial read voltage and the compensation value.

7. The method of the memory system of claim 6, wherein:
the obtaining of the first set of read reference voltages based on the first set of read results and level indicators of the multiple target memory cells comprises:
obtaining 2^{N-1}−1 different first read reference voltages in the first set of read reference voltages based on the first set of read results and inverted level indicators of the multiple target memory cells; and
the obtaining of the second set of read reference voltages based on the second set of read results and level indicators of the multiple target memory cells comprises:
obtaining 2^{N-1}−1 different second read reference voltages in the second set of read reference voltages based on the second set of read results and level indicators of the multiple target memory cells.

8. The method of the memory system of claim 7, wherein the obtaining of the 2^{N-1}−1 different first read reference voltages in the first set of read reference voltages based on the first set of read results and inverted level indicators of the multiple target memory cells comprises:
obtaining a number of memory cells that store a first value in the first set of memory cells corresponding to each read voltage of an X-th set of first read operations in the 2^{N-1}−1 sets of first read operations based on read results of the X-th set of first read operations and inverted level indicators of the multiple target memory cells, wherein X is a positive integer;
calculating differences between numbers of memory cells that store the first value in the first set of memory cells corresponding to two adjacent read voltages in the X-th set of first read operations, and determining an X-th first read reference voltage in the 2^{N-1}−1 different first read reference voltages based on a minimum of the differences; or
calculating a ratio of the number of memory cells that store the first value in the first set of memory cells corresponding to each read voltage in the X-th set of first read operations to the number of memory cells in the first set of memory cells, and determining an X-th first read reference voltage in the 2^{N-1}−1 different first read reference voltages based on a comparison of the ratio and X×2^{1-N}.

9. The method of the memory system of claim 7, wherein the obtaining of the 2^{N-1}−1 different second read reference voltages in the second set of read reference voltages based on the second set of read results and level indicators of the multiple target memory cells comprises:
obtaining a number of memory cells that store a first value in the second set of memory cells corresponding to each read voltage of a Y-th set of second read operations in the 2^{N-1}−1 sets of second read operations based on read results of the Y-th set of second read operations and level indicators of the multiple target memory cells, wherein Y is a positive integer; and
calculating differences between numbers of memory cells that store the first value in the second set of memory cells corresponding to two adjacent read voltages in the Y-th set of second read operations, and determining a Y-th second read reference voltage in the 2^{N-1}−1 different second read reference voltages based on a minimum of the differences; or
calculating a ratio of the number of memory cells that store the first value in the second set of memory cells corresponding to each read voltage in the Y-th set of second read operations to the number of memory cells in the second set of memory cells, and determining a Y-th second read reference voltage in the 2^{N-1}−1 different second read reference voltages based on a comparison of the ratio and Y×2^{1-N}.

10. The method of the memory system of claim 4, wherein the performing of the plurality of third read operations on the multiple target memory cells based on the first set of read reference voltages and the second set of read reference voltages to obtain the third set of read results comprises:
using a first default read voltage of the first set of memory cells, a last default read voltage of the second set of memory cells, the first set of read reference voltages and the second set of read reference voltages as a third set of read voltages, wherein the first default read voltage of the first set of memory cells is less than a minimum first initial read voltage of the 2^{N-1}−1 first initial read voltages, and the last default read voltage of the second set of memory cells is greater than a maximum second initial read voltage of the 2^{N-1}−1 second initial read voltages; and
performing N sets of third read operations on the multiple target memory cells based on the third set of read voltages to obtain the third set of read results.

11. The method of the memory system of claim 10, wherein performing each of the third read operations comprises:
performing a first sub-read operation to obtain a first sub-read result, wherein a read voltage of the first sub-read operation includes a first read reference voltage; and
performing a second sub-read operation to obtain a second sub-read result, wherein a read voltage of the second sub-read operation includes a second read reference voltage,
wherein the obtaining of the data stored in the multiple target memory cells based on the third set of read results and level indicators of the multiple target memory cells comprises:
obtaining one bit of data in the N bits of data stored in each target memory cell based on an operation result of the first sub-read result and inverted level indicators of the multiple target memory cells and an operation result of the second sub-read result and level indicators of the multiple target memory cells.

12. A controller, comprising:
a processor; and
an interface coupled to a memory device,
wherein the processor is configured to:
transmit a first read command and a second read command through the interface, wherein the first read command instructs to perform first read operations on multiple target memory cells with a first set of read voltages, and the second read command instructs to perform second read operations on the multiple target memory cells with a second set of read voltages;
obtain a first set of read reference voltages based on a first set of read results of the first read operations and level indicators of the multiple target memory cells;
obtain a second set of read reference voltages based on a second set of read results of the second read operations and a level indicator of the multiple target memory cells; and
transmit a third read command through the interface, wherein the third read command instructs to perform third read operations on the multiple target memory cells with the first set of read reference voltages and the second set of read reference voltages.

13. The controller of claim 12, wherein the processor is further configured to:
obtain data stored in the multiple target memory cells based on a third set of read results of the third read operations and level indicators of the multiple target memory cells.

14. The controller of claim 13, wherein the processor is further configured to:
obtain a level indicator of each target memory cell based on N bits of data stored in each target memory cell, wherein the multiple target memory cells include a first set of memory cells that store 2^{N-1} different types of data and a second set of memory cells that store 2^{N-1} different types of data, and wherein a level indicator of the first set of memory cells is different from a level indicator of the second set of memory cells.

15. The controller of claim 14, wherein the processor is further configured to:
acquire 2^{N-1}−1 default read voltages of the second set of memory cells as 2^{N-1}−1 first initial read voltages in the first set of read voltages; and
acquire 2^{N-1}−1 default read voltages of the first set of memory cells as 2^{N-1}−1 second initial read voltages in the second set of read voltages,
wherein an M-th first initial read voltage in the 2^{N-1}−1 first initial read voltages is less than an M-th second initial read voltage in the 2^{N-1}−1 second initial read voltages, and the M-th first initial read voltage in the 2^{N-1}−1 first initial read voltages is greater than an (M−1)th second initial read voltage in the 2^{N-1}−1 second initial read voltages, wherein M is an integer greater than 1.

16. The controller of claim 15, wherein the processor is further configured to:
obtain multiple different first compensation read voltages in the first set of read voltages based on the 2^{N-1}−1 first initial read voltages and a compensation value; and
obtain multiple different second compensation read voltages in the second set of read voltages based on the 2^{N-1}−1 second initial read voltages and the compensation value.

17. The controller of claim 14, wherein the processor is configured to:
obtain 2^{N-1}−1 different first read reference voltages in the first set of read reference voltages based on the first set of read results and inverted level indicators of the multiple target memory cells; and
obtain 2^{N-1}−1 different second read reference voltages in the second set of read reference voltages based on the second set of read results and level indicators of the multiple target memory cells.

18. A memory system comprising:
a memory device; and
a controller coupled to the memory device,
wherein:
the controller is configured to:
transmit a first read command and a second read command, wherein the first read command instructs to perform first read operations on multiple target memory cells in the memory device with a first set of read voltages, and the second read command instructs to perform second read operations on the multiple target memory cells with a second set of read voltages;
the memory device is configured to:
in response to the first read command, perform a plurality of first read operations on the multiple target memory cells based on the first set of read voltages to obtain a first set of read results, and transmit the first set of read results; and
in response to the second read command, perform a plurality of second read operations on the multiple target memory cells based on the second set of read voltages to obtain a second set of read results, and transmit the second set of read results;
the controller is further configured to:
obtain a first set of read reference voltages based on the first set of read results and level indicators of the multiple target memory cells;
obtain a second set of read reference voltages based on the second set of read results and level indicators of the multiple target memory cells; and
transmit a third read command, wherein the third read command instructs to perform third read operations on the multiple target memory cells with the first set of read reference voltages and the second set of read reference voltages; and
the memory device is further configured to:
in response to the third read command, perform a plurality of third read operations on the multiple target memory cells based on the first set of read reference voltages and the second set of read reference voltages to obtain a third set of read results, and transmit the third set of read results.

19. The memory system of claim 18, wherein the controller is further configured to:
obtain data stored in the multiple target memory cells based on the third set of read results and level indicators of the multiple target memory cells.

20. The memory system of claim 19, wherein any one of the multiple target memory cells stores N bits of data, wherein N is an integer greater than 1; and
the controller is further configured to:
obtain a level indicator of each target memory cell based on the N bits of data stored in each target memory cell, wherein the multiple target memory cells include a first set of memory cells that store 2^{N-1} different types of data and a second set of memory cells that store 2^{N-1} different types of data, and wherein a level indicator of the first set of memory cells is different from a level indicator of the second set of memory cells.
